(19) United States
(12) Patent Application Publication
(10) Pub. No.: US 2022/0397498 A1
(43) Pub. Date: Dec. 15, 2022

(54) METHOD FOR PROCESSING SCANNING ELECTRON MICROSCOPE SPECIMEN

(71) Applicants: Tsinghua University, Beijing (CN); HON HAI PRECISION INDUSTRY CO., LTD., New Taipei (TW)

(72) Inventors: XIN-YU GAO, Beijing (CN); GUO CHEN, Beijing (CN); KE ZHANG, Beijing (CN); LIN CONG, Beijing (CN); KAI-LI JIANG, Beijing (CN); SHOU-SHAN FAN, Beijing (CN)

(21) Appl. No.: 17/679,646

(22) Filed: Feb. 24, 2022

(30) Foreign Application Priority Data
Jun. 9, 2021 (CN) 202110640244.6

(51) Int. Cl. G01N 1/36; H01J 37/28; H01J 37/244; C01B 32/168

(52) U.S. Cl. CPC G01N 1/36; H01J 37/28; H01J 37/244; C01B 32/168; H01J 2237/20; C01B 2202/08; C01B 2202/30

(57) ABSTRACT

A method for processing scanning electron microscope specimen is provided. The method comprises: providing a specimen to be observed; providing a carbon nanotube array comprising a plurality of carbon nanotubes; and pulling a carbon nanotube film from the carbon nanotube array, and laying the carbon nanotube film on a surface of the specimen, wherein the carbon nanotube film comprising a plurality of through holes.

### CROSS-REFERENCE TO RELATED APPLICATIONS

This application claims all benefits accruing under 35 U.S.C. § 119 from China Patent Application No. 202110640244.6, filed on Jun. 9, 2021, in the China Intellectual Property Office, the contents of which are hereby incorporated by reference.

### FIELD

The present disclosure relates to a method for processing scanning microscope specimen.

### BACKGROUND

Scanning Electron Microscope (SEM) is an electron optical instrument which mainly uses secondary electron signal imaging to observe a surface morphology of a specimen by the secondary electron emission of the specimen. The secondary electrons can produce an enlarged image of the surface of the specimen. This image is established in time sequence when the specimen is scanned, that is, an enlarged image is obtained using point-by-point imaging. However, for specimens with no or poor conductivity, the electrons generated under high accelerating voltage cannot be directed to the ground, thereby forming a charging effect on the surface of the specimen, which affects the SEM imaging observation. In a conventional solution method, a conductive layer, such as gold, platinum, carbon, etc., is sprayed or evaporated on the surface of the specimen to reduce the charging effect. However, after the conductive layer is formed on the surface of the specimen, it may not be completely removed from the specimen, which may prohibit the specimen to be used again.

### BRIEF DESCRIPTION OF THE DRAWINGS

Implementations of the present technology will now be described, by way of example only, with reference to the attached figures, wherein:

FIG. 1 is a flowchart of a method for processing a scanning electron microscope specimen according to one embodiment.

FIG. 2 is a scanning electron micrograph (SEM) image of a carbon nanotube film according to one embodiment.

FIG. 3 is an SEM image of a specimen of a “THU” letter pattern etched on a surface of a single crystal magnesium oxide substrate in one embodiment.

FIG. 4 is an SEM image of a processed specimen obtained by processing the specimen in FIG. 3 with the method for processing scanning electron microscope specimen.

FIG. 5 shows SEM images obtained under different accelerating voltages of the processed specimen in FIG. 4 (after processed).

FIG. 6 is an SEM image of a “THU” letter pattern on the surface of a quartz glass substrate (unprocessed).

FIG. 7 is an SEM image of a processed specimen obtained by processing the specimen in FIG. 6 with the method for processing scanning electron microscope specimen.

FIG. 8 is an SEM image of another specimen obtained by pealing off a carbon nanotube film from the processed specimen in FIG. 7.

FIG. 9 is an SEM image of another processed specimen obtained by processing the specimen in FIG. 6 with a conventional processing method.

FIG. 10 is an SEM image of another specimen obtained by removing a conductive glue from the processed specimen in FIG. 9.

FIG. 11 is a photograph of a partial area in the SEM image of FIG. 6 when the magnification is 20000 times.

FIG. 12 is a photograph of a partial area in the SEM image of FIG. 8 when the magnification is 20000 times.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “include, but not necessarily limited to”; it specifically indicates open-ended inclusion or membership in the so-described combination, group, series, and the like.

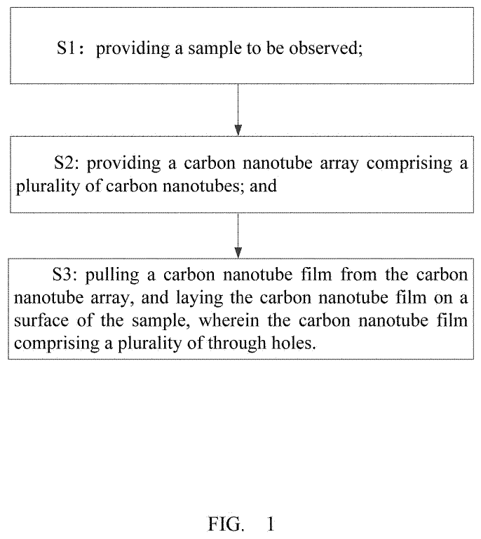

Referring to FIG. 1, a method for processing scanning electron microscope specimen according to one embodiment is provided. The method comprises steps:

S1: providing a specimen to be observed;

S2: providing a carbon nanotube array comprising a plurality of carbon nanotubes; and

S3: pulling a carbon nanotube film from the carbon nanotube array, and laying the carbon nanotube film on a surface of the specimen, wherein the carbon nanotube film comprising a plurality of through holes.

In step S1, the specimen to be observed is an insulating material or a material with poor conductivity.

In step S2, the carbon nanotube array basically does not contain impurities, such as amorphous carbon or residual catalyst metal particles. Since the plurality of carbon nanotubes are basically free of impurities and the plurality of carbon nanotubes are in close contact with each other, and a substantial van der Waals attractive force can exist between adjacent carbon nanotubes. The carbon nanotubes in the carbon nanotube array are arranged side by side. Each carbon nanotube has a cylinder structure, and defines an axial direction. An out surface of the cylinder structure is a side surface of the carbon nanotube. The carbon nanotubes arranged side by side means that side surfaces of the carbon nanotubes are connected with each other. When some carbon nanotubes are pulled from the carbon nanotube array, the carbon nanotubes in the carbon nanotube array are connected end to end through van der Waals attractive force and continuously pulled out to form a continuous self-supporting macroscopic structure, that is, a carbon nanotube film. The carbon nanotube array is also called a super-aligned carbon nanotube array. A preparation method of the super-aligned carbon nanotube array is not limited, and a chemical vapor deposition method is adopted in one embodiment.

In step S3, a stretching tool is used to select a carbon nanotube bundle with a certain width from the carbon nanotube array; the stretching tool is moved in a direction away from the carbon nanotube array to pull the selected carbon nanotube bundle, and the carbon nanotubes in the carbon nanotube array are drawn out from the carbon nanotube array continuously. The carbon nanotubes drawn out from the carbon nanotube array are joined end to end, thereby forming a continuous carbon nanotube film. The carbon nanotube bundle includes a plurality of carbon nanotubes arranged side by side. After the carbon nanotube film is drawn from the carbon nanotube array, it is directly laid on the surface of the specimen to be observed, and then the excess carbon nanotube film is cut off. The surface of the specimen to be observed is covered by a single layer of the carbon nanotube film.

In step S3, it is only necessary to lay a single layer of carbon nanotube film on the surface of the scanning electron microscope specimen, and there is no need to lay multiple layers of carbon nanotube films.

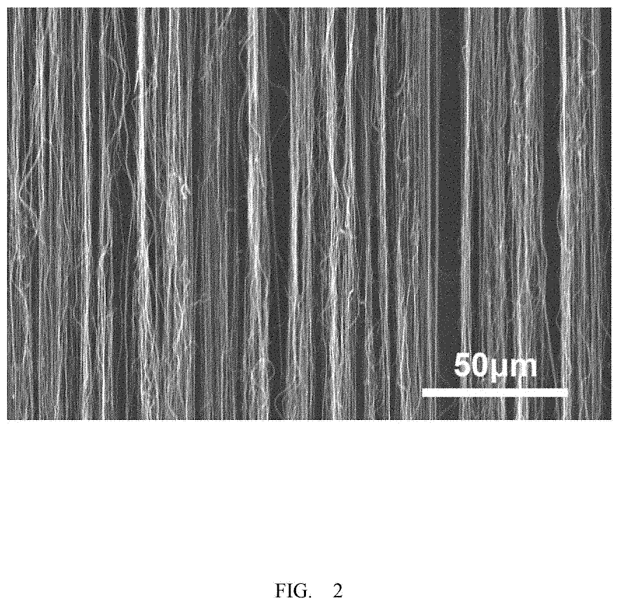

The carbon nanotube film continuously drawn from the carbon nanotube array includes a plurality of carbon nanotubes joined end to end by van der Waals attractive force. The carbon nanotube film is a self-standing carbon nanotube film. The carbon nanotube film includes a plurality of carbon nanotubes arranged substantially along a same direction. Referring to FIG. 2, the carbon nanotubes in the carbon nanotube film are arranged in a preferred orientation along the same direction, which means that most of the carbon nanotubes in the carbon nanotube film are basically arranged in the same direction, and are parallel with a surface of the carbon nanotube film. The most of the carbon nanotubes in the carbon nanotube film extending in the same direction are joined end to end with the adjacent carbon nanotubes in the extension direction via van der Waals attractive force, so that the carbon nanotube film a self-standing structure. The carbon nanotube film defines a plurality of gaps, that is, there is a plurality of gaps between adjacent carbon nanotubes, as such, the carbon nanotube film has a better transparency. The gaps between the carbon nanotubes in the carbon nanotube film are through holes in the carbon nanotube film. Sizes of the gaps are in a range from 20 nanometers to 10 micrometers.

After completing the scanning electron microscope observation, a step of separating the carbon nanotube film from the specimen is further provided. This step includes: placing the specimen with the carbon nanotube film in pure water and ultrasonically treating it for 5-10 minutes. Then, the carbon nanotube film is separated from the specimen. After the separation, no carbon nanotubes remain on the surface of the specimen, which will not affect a reuse of the specimen.

The scanning electron microscope specimen processing method provided by the present invention has the following advantages: a layer of carbon nanotube film is laid on the surface of the specimen, because the carbon nanotubes in the carbon nanotube film have good conductivity, in the observation process, electrons on the surface of the specimen are led away by the carbon nanotubes, thereby preventing the charging effect on the surface of the specimen. The specimen processed by the scanning electron microscope specimen processing method can be clear observed under the scanning electron microscope without spraying metal plating or coating conductive glue on the surface of the specimen. At the same time, because the carbon nanotube film is an integral structure and is less viscous, the carbon nanotube film can be torn off the specimen directly without residue, and which will not cause damage to the specimen.

Comparative Test 1:

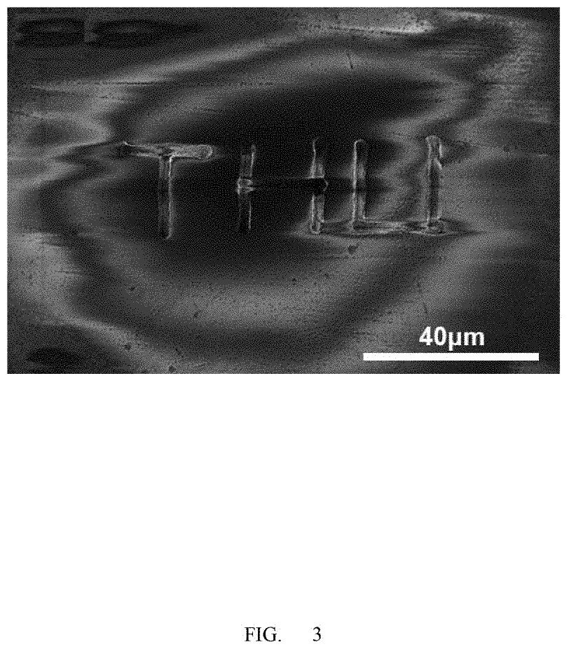

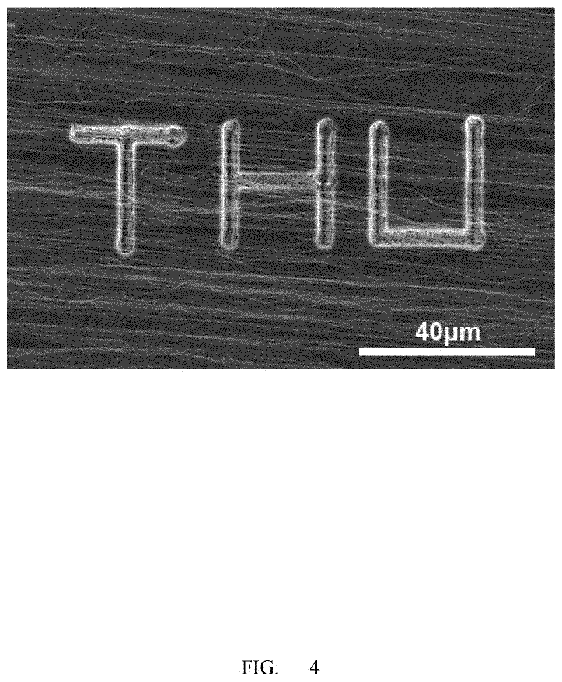

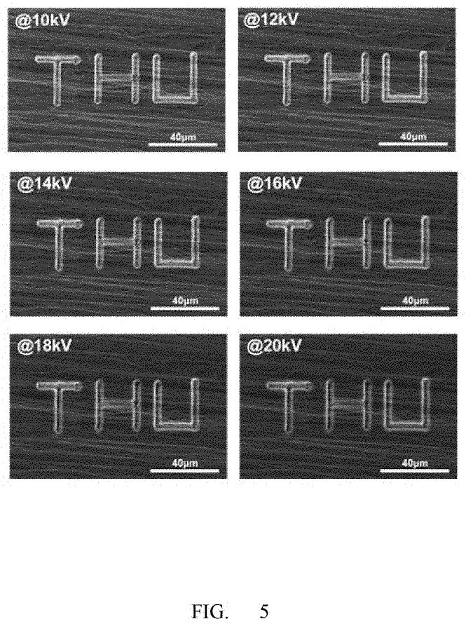

A single crystal magnesium oxide substrate is provided, and a “THU” letter pattern is etched on the surface of the single crystal magnesium oxide substrate to obtain a specimen to be observed. The specimen is observed under a scanning electron microscope. Referring to FIG. 3, the specimen (untreated) was directly observed with a scanning electron microscope. Since the single crystal magnesium oxide is an insulating material, a charging effect is generated on the surface of the specimen, which affects the scanning electron microscope (SEM) imaging observation. Therefore, the obtained SEM image is not clear, and the surface of the single crystal magnesium oxide substrate can not be observed clearly. Referring to FIG. 4, after the specimen is processed by a method for processing scanning electron microscope specimen provided by the present disclosure, a clear SEM image is obtained, and the specimen surface can be clearly observed. The comparative test 1 shows that the specimen processed by the method for processing scanning electron microscope specimen of the present invention can be clearly observed under the SEM without spraying metal plating or coating on the surface of the specimen. Referring to FIG. 5, the specimen processed by the method for processing scanning electron microscope specimen can be clearly observed under different acceleration voltages, under the scanning electron microscope.

Comparative Test 2:

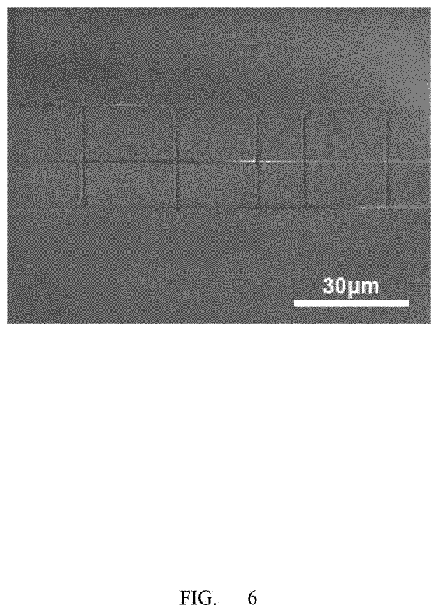

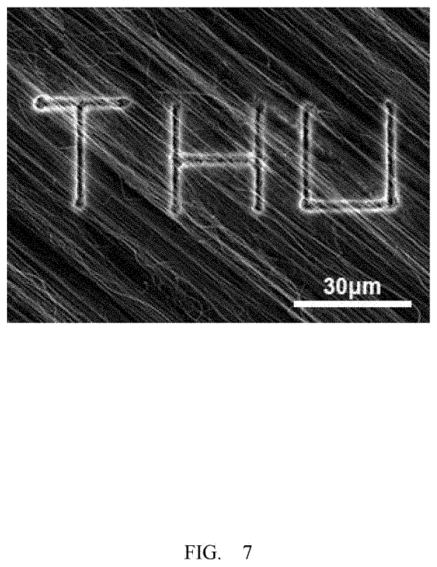

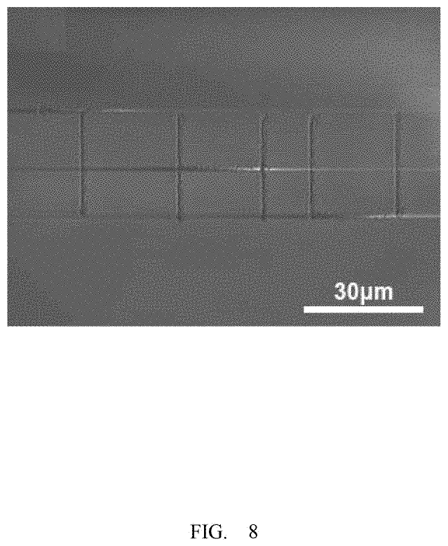

A quartz glass substrate is provided, and a “THU” letter pattern is etched on a surface of the substrate to obtain a specimen to be observed, and the specimen is observed under a scanning electron microscope. Referring to FIG. 6, the specimen (unprocessed) is directly observed with an SEM. Because quartz glass is an insulating material, a charging effect is generated on the surface of the specimen when the specimen is observed under the SEM, which affects the imaging observation of the SEM. Therefore, the obtained SEM image cannot clearly show the surface of the specimen. Referring to FIG. 7, after the specimen is processed by the method for processing scanning electron microscope specimen provided by the present invention, that is, a carbon nanotube film is laid on the surface of the specimen, the surface of the specimen can be clearly observed. After completing the observation of the specimen, the carbon nanotube film on the surface of the specimen is peeled off, and then observed under the SEM, referring to FIG. 8, it can be seen that, there is no residual carbon nanotubes on the surface of the specimen. This shows that because the carbon nanotube film exists in the form of a monolithic film and is less viscous, the carbon nanotube film can be removed directly from the specimen without residue, which will not cause damage to the specimen.

Comparative Test 3:

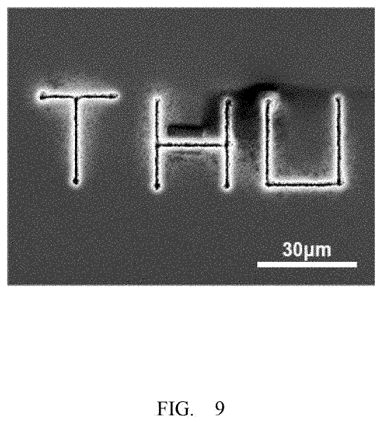

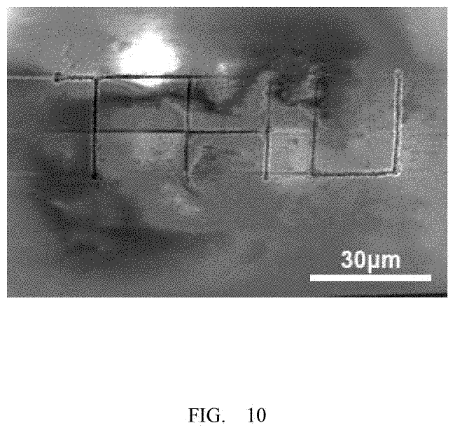

A quartz glass substrate is provided, and a “THU” letter pattern is etched on the surface of the substrate to obtain a specimen to be observed. The specimen is observed under an SEM. Referring to FIG. 9, the specimen is processed by a conventional method, that is, a layer of conductive glue is coated on the surface of the specimen, and the image of the specimen surface is also clearly observed. Referring to FIG. 10, after completing the observation of the specimen, removing the conductive glue on the specimen surface, and then observing under the SEM. It can be confirmed that there is residual conductive glue on the specimen surface, and the conductive glue cannot be completely separated from the specimen. Therefore, the specimen cannot be used again.

Comparative Test 4:

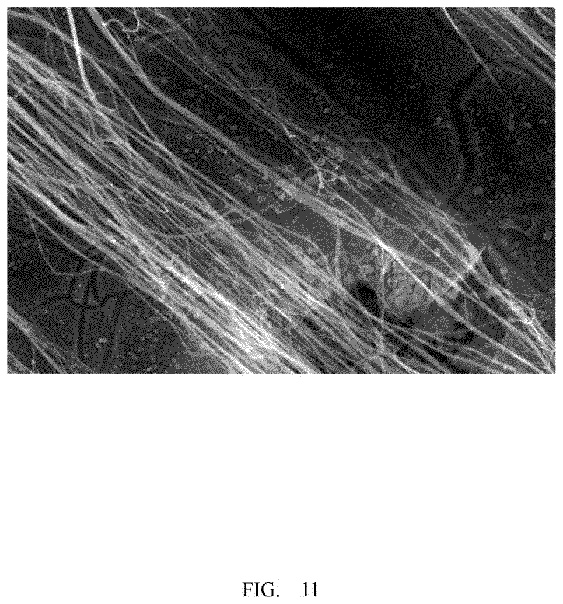

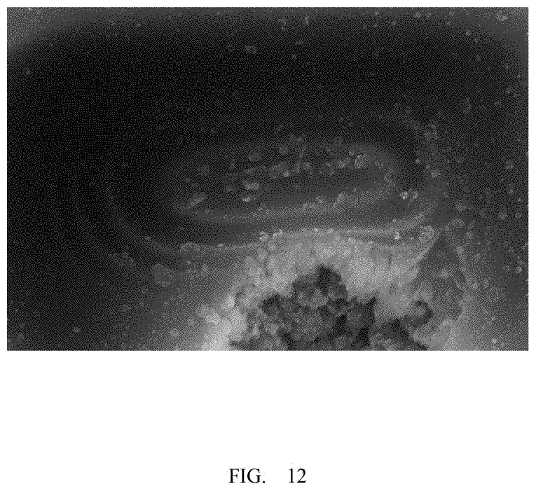

A first specimen and a second specimen are provided, and they are same specimens. Each specimen is a quartz glass substrate with a “THU” letter pattern etched on the surface of the substrate. The first specimen was processed by a method for processing scanning electron microscope specimen provided by the present invention, that is, a layer of carbon nanotube film was laid on the surface of the first specimen. The second specimen is processed by a conventional method, that is, coating a layer of conductive glue on the surface of the second specimen. The first specimen and the second specimen are both observed under an acceleration voltage of 15 kV and for more than 5 minutes, and the magnification was 20000 times. Refer to FIG. 11, there is no change on the surface of first specimen. Referring to FIG. 12, the conductive glue coated on the surface of second specimen is carbonized, and then the conductive glue is denatured. This shows that compared with conventional specimen processing method, the method for processing scanning electron microscope specimen provided by the present invention is more suitable for observation under high magnification.

It is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described may be removed, others may be added, and the sequence of steps may be altered. The description and the claims drawn to a method may include some indication in reference to certain steps. However, the indication used is only to be viewed for identification purposes and not as a suggestion as to an order for the steps.

What is claimed is:

1. A method of processing a specimen for scanning electron microscope comprising:
providing the specimen;
providing a carbon nanotube array comprising a plurality of carbon nanotubes; and
forming a carbon nanotube film from the carbon nanotube array, and
laying the carbon nanotube film on a surface of the specimen, wherein the carbon nanotube film comprising a plurality of through holes.

2. The method of claim 1, wherein a material of the specimen is an insulating material.

3. The method of claim 1, wherein the carbon nanotube array is a super-aligned carbon nanotube array.

4. The method of claim 3, wherein the plurality of carbon nanotubes are substantially free of impurities and the plurality of carbon nanotubes are in close contact with each other.

5. The method of claim 1, wherein the carbon nanotube film are formed by pulling a starting portion of carbon nanotubes from a substrate that supports the carbon nanotube array, and continuously pulling out a remaining portion of the carbon nanotubes from the substrate to form the carbon nanotube film, the carbon nanotube film is a continuous self-supporting macroscopic structure comprising the carbon nanotubes interconnected end to end through van der Waals attractive force.

6. The method of claim 1, wherein a stretching tool is used to select a carbon nanotube bundle with a certain width from the carbon nanotube array; the stretching tool is moved in a direction away from the carbon nanotube array to pull the selected carbon nanotube bundle, and the carbon nanotubes in the carbon nanotube array are drawn out from the carbon nanotube array continuously to form the carbon nanotube film.

7. The method of claim 6, wherein the carbon nanotube bundle comprises carbon nanotubes arranged side by side.

8. The method of claim 6, wherein the carbon nanotubes drawn out from the carbon nanotube array are joined end to end to the carbon nanotube film which is continuous.

9. The method claim 1, wherein after the carbon nanotube film is drawn from the carbon nanotube array, the carbon nanotube film is directly laid on the surface of the specimen, and an excess carbon nanotube film is trimmed off.

10. The method of claim 1, wherein the surface of the specimen is covered by a single layer of the carbon nanotube film.

11. The method of claim 1, wherein most of the plurality of carbon nanotubes in the carbon nanotube film extending in a same direction are joined end to end with adjacent carbon nanotubes in the direction via van der Waals attractive force.

12. The method of claim 1, wherein sizes of the plurality of through hole are in a range from 20 nanometers to 10 micrometers.

13. The method of claim 1, further comprising separating the carbon nanotube film from the specimen.

14. The method of claim 12, wherein the carbon nanotube film is separated from the specimen by placing the specimen with the carbon nanotube film in water and ultrasonically treating for 5 to 10 minutes.
